(19) United States
(12) Patent Application Publication
(10) Pub. No.: US 2006/0120202 A1
(43) Pub. Date: Jun. 8, 2006

(54) Data driver chip and light emitting display

(76) Inventors: Yang Wan Kim, Seoul (KR); Oh Kyong Kwon, Seoul (KR)

Correspondence Address: H.C. PARK & ASSOCIATES, PLC, 8500 LEESBURG PIKE, SUITE 7500, VIENNA, VA, 22182, US

(21) Appl. No.: 11/273,037

(22) Filed: Nov. 15, 2005

(30) Foreign Application Priority Data
Nov. 17, 2004 (KR) 10-2004-0094188
Nov. 23, 2004 (KR) 10-2004-0096379

(51) Int. Cl. G11C 8/00

(52) U.S. Cl. 365/230.06

(57) ABSTRACT

A light emitting display includes a scan driver applying scan signals to a plurality of scan lines, a data driver applying data currents to a plurality of data lines, and an image display unit for displaying images in accordance with the scan signals and the data currents. The data driver comprises a first data driver chip for outputting a reference current determined by a reference voltage and a resistance and a second data driver chip for receiving the reference current from the first data driver chip.

### CROSS-REFERENCE TO RELATED APPLICATIONS

This application claims priority to and the benefit of Korean Patent Application No. 10-2004-0094188, filed on Nov. 17, 2004 and Korean Patent Application No. 10-2004-0096379, filed on Nov. 23, 2004, which are hereby incorporated by reference for all purposes as if fully set forth herein.

### BACKGROUND OF THE INVENTION

1. Field of the Invention

The present invention relates to a data driver chip and a light emitting display, and more particularly, to a data driver chip and a light emitting display that may provide more uniform reference currents.

2. Discussion of the Background

Recently, various flat panel displays have been developed to replace bulkier and heavier cathode ray tubes (CRT). Such flat panel displays include liquid crystal displays (LCD), field emission displays (FED), plasma display panels (PDP), and light emitting displays.

Among the flat panel displays, the light emitting displays are self-emissive devices that emit light by re-combination of electrons and holes. An inorganic light emitting display includes an inorganic emission layer, and an organic light emitting display includes an organic emission layer. The organic light emitting display may be referred to as an organic electroluminescent display. Like the CRT, the light emitting display may have high response speed compared with a device that requires a light source such as an LCD.

The light emitting display may be driven by a passive matrix method and an active matrix method. According to the passive matrix method, an anode and a cathode are formed in rows and columns, and row and column lines-are selected to be driven. According to the active matrix method, an active device controls the amount of current that flows through an electroluminescent device. A thin film transistor (TFT) is typically used as the active device. While the active matrix method is complicated, it consumes little power and provides a long emission time.

The programming method of the light emitting display includes a voltage programming method and a current programming method. According to the voltage programming method, a data driver outputs voltages corresponding to data signals. When using the voltage programming method, it is possible to use an LCD's data driver, however, it is difficult to obtain a uniform image due to deviation between the threshold voltage and mobility of the TFT used as the active device. According to the current programming method, the data driver outputs currents corresponding to the data signals. Hence, the current programming method may compensate for the deviation between the threshold voltage and mobility of the TFT to thus obtain a uniform image.

On the other hand, as the light emitting display's size and resolution increase, the number of data lines increases. Therefore, it may be technically easier to configure the data driver using a plurality of data driver chips rather than one data driver chip.

FIG. 1 schematically illustrates a conventional data driver including a plurality of data driver chips.

Referring to FIG. 1, the data driver includes first, second, third and fourth data driver chips 10, 20, 30 and 40. Since each data driver chip 10, 20, 30 and 40 has 300 channel outputs, the data driver may have a maximum of 1,200 channel outputs. The data driver chips 10 to 40 generate reference currents using a reference voltage Vref and external resistances Rext1, Rext2, Rext3 and Rext4. The generated reference currents are used by digital to analog (D/A) converters (not shown) arranged in the data driver chips 10 to 40. When the reference currents change, the data current values corresponding to gray scales change so that brightness of the pixel connected to each data line changes. Therefore, when the data driver chips have different reference current values, a brightness difference exists among the pixels connected to the data driver chips 10, 20, 30 and 40. Consequently, picture quality becomes non-uniform. Generally, a difference may exist among external resistance values due to factors such as deviation in a manufacturing processes and temperature. Therefore, the data driver chips 10 to 40 may have different reference currents, which may result in non-uniform picture quality.

### SUMMARY OF THE INVENTION

The present invention provides a data driver chip and a light emitting display that may provide more uniform reference currents used by data driver chips to improve uniformity in picture quality.

Additional features of the invention will be set forth in the description which follows, and in part will be apparent from the description, or may be learned by practice of the invention.

The present invention discloses a light emitting display including a scan driver for applying scan signals to a plurality of scan lines, a data driver for applying data currents to a plurality of data lines, and an image display unit for displaying images in accordance with the scan signals and the data currents. The data driver comprises a first data driver chip for outputting a reference current and a second data driver chip for receiving the reference current output from the first data driver chip.

The present invention also discloses a light emitting display including a scan driver for applying scan signals to a plurality of scan lines, a data driver for applying data currents to a plurality of data lines, and an image display unit for displaying images in accordance with the scan signals and the data currents. The data driver comprises a first data driver chip for outputting differential reference currents and a second data driver chip for receiving the differential reference currents output from the first data driver chip.

The present invention also discloses a data driver chip including a shift register for outputting a latch control signal in response to a clock signal and a synchronizing signal, a data latch for sequentially receiving video data to output the video data in parallel in accordance with the latch control signal, a D/A converter for outputting data currents obtained by analog converting the video data output of the data latch, and a bias circuit. The bias circuit generates a reference current and an output reference current using a reference voltage and a resistance when a first control signal is applied, generates the reference current and the output reference current using an input reference current when a second control signal is applied, and transmits the generated reference current to the D/A converter and outputs the output reference current.

The present invention also discloses a data driver chip including a shift register for outputting a latch control signal in response to a clock signal and a synchronizing signal, a data latch for sequentially receiving video data to output the video data in parallel in accordance with the latch control signal, a D/A converter for outputting data currents obtained by analog converting the video data output of the data latch, and a bias circuit. The bias circuit generates a reference current and output differential reference currents using a reference voltage and a resistance when a first control signal is applied, generates the reference current and the output differential reference currents using input differential reference currents when a second control signal is applied, and transmits the reference current to the D/A converter and outputs the output differential reference currents.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 schematically shows a conventional data driver including a plurality of data driver chips.

FIG. 2 shows a light emitting display according to an exemplary embodiment of the present invention.

FIG. 3 schematically shows a data driver that has a plurality of data driver chips and that may be used for the light emitting display of FIG. 2 according to a first exemplary embodiment of the present invention.

FIG. 4 schematically shows a data driver that has a plurality of data driver chips and that may be used for the light emitting display of FIG. 2 according to a second exemplary embodiment of the present invention.

FIG. 5 shows an example of a data driver chip that may be used for the data driver of FIG. 4.

FIG. 6 shows an example of a bias circuit that may be used for the data driver chip of FIG. 5.

FIG. 7 shows an example of a current generating circuit that may be used for the data driver according to the first and second exemplary embodiments of the present invention.

FIG. 8 shows an example of a data driver chip that may be used for the light emitting display of FIG. 2 according to an exemplary embodiment of the present invention.

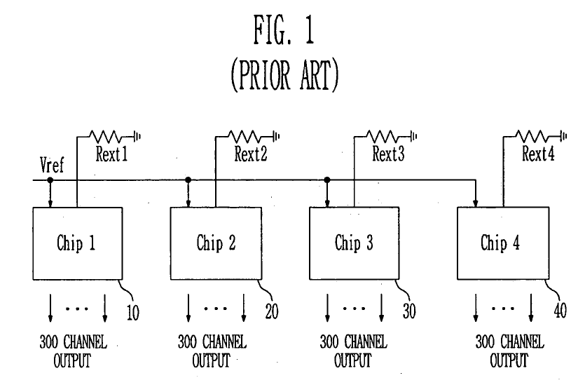

### DETAILED DESCRIPTION OF ILLUSTRATED EMBODIMENTS

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art.

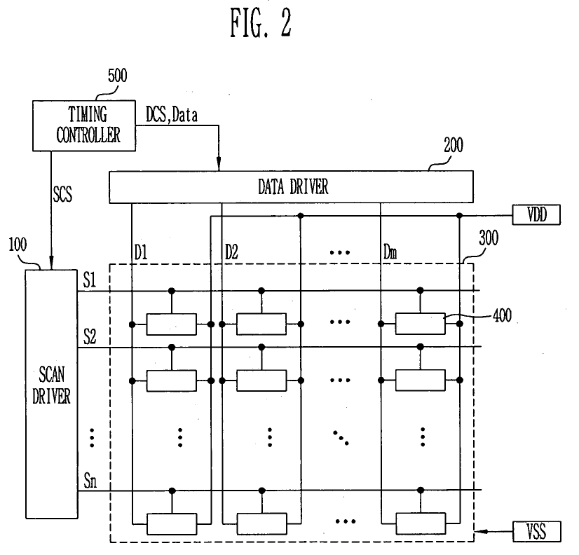

FIG. 2 shows a light emitting display according to an exemplary embodiment of the present invention.

Referring to FIG. 2, the light emitting display includes a scan driver 100, a data driver 200, an image display unit 300, and a timing controller 500.

The scan driver 100 drives scan lines S1 to Sn. The scan driver 100 generates scan signals in response to scan driver control signals SCS and supplies the generated scan signals to the scan lines S1 to Sn. For example, the scan driver 100 may sequentially supply the generated scan signals to the scan lines S1 to Sn.

The data driver 200 drives data lines D1 to Dm. The data driver 200 generates data currents in response to data driver control signals DCS and video data Data and supplies the generated data currents to the data lines D1 to Dm. The data driver 200 includes a plurality of data driver chips (not shown). A first data driver chip among the plurality of data driver chips generates a reference current or differential reference currents using a reference voltage and an external resistance, and the other data driver chips use the reference current or the differential reference currents received from another data driver chip to generate a reference current or differential reference currents.

The image display unit 300 includes a plurality of pixels 400, which are defined by the scan lines S1 to Sn and the data lines D1 to Dm. Also, the image display unit 300 receives a first power source voltage VDD and a second power source voltage VSS. Here, the first power source voltage VDD and the second power source voltage VSS are transmitted to the pixels 400. Each pixel 400 displays an image corresponding to the data current supplied thereto.

The timing controller 500 supplies the scan driver control signals SCS to the scan driver 100 and the data driver control signals DCS and the video data Data to the data driver 200.

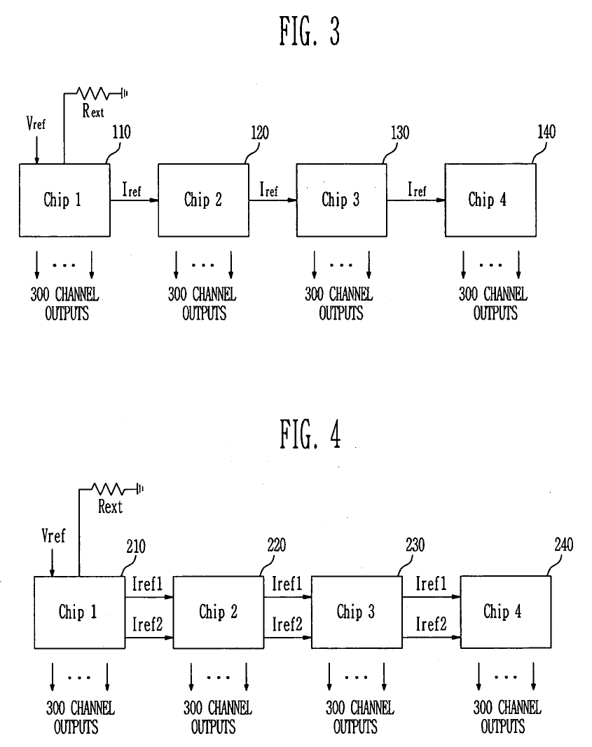

FIG. 3 schematically shows a data driver that has a plurality of data driver chips and that may be used for the light emitting display of FIG. 2 according to a first exemplary embodiment of the present invention.

Referring to FIG. 3, the data driver according to the first exemplary embodiment of the present invention includes a plurality of data driver chips 110, 120, 130, and 140 so as to provide channels according to the size of the light emitting display's screen. Each data driver chip is formed of a semiconductor chip and is preferably manufactured to have substantially the same structure. The first data driver chip 110 may be a master data driver chip, and the second, third, and fourth data driver chips 120, 130, and 140 may be slave data driver chips, which are coupled with the master data driver chip 110. According to the present embodiment, each data driver chip includes 300 channel outputs and supplies a predetermined data signal to a data line coupled with each channel output.

The first data driver chip 110 is electrically coupled with a resistance Rext and receives a predetermined reference voltage Vref. The first data driver chip 110 generates a reference current Iref based on the resistance Rext and the reference voltage Vref. Also, the first data driver chip 110 converts input digital video data into analog data signals, based on the generated reference current Iref, to output the analog data signals.

The second data driver chip 120 receives the reference current Iref from the first data driver chip 110. The second data driver chip 120 converts input digital video data into analog data signals, based on the reference current Iref received from the first data driver chip 110, to output the analog data signals. Here, the reference current Iref may be obtained by copying the reference current Iref generated by the first data driver chip 110.

The third and fourth data driver chips 130 and 140 have substantially the same structure as the second data driver chip 120. Therefore, a detailed description of the third and fourth data driver chips 130 and 140 will be omitted in order to avoid redundancy.

According to the present embodiment, the reference current Iref generated by the first data driver chip 110 may be obtained by dividing the reference voltage Vref by the resistance Rext, which is arranged outside the first driver chip 110.

The reference currents Iref determine the maximum value and one least significant bit 1 LSB of the digital/analog converters in the data driver chips. Therefore, deviations in the reference current values applied to the integrated circuits in the data driving circuits cause deviations in output currents of the integrated circuits. That is, with a conventional data driver, the resistances of the external resistors may vary by as much as 1 to 10% due to factors such as deviation in manufacturing processes and temperature. Therefore, deviation in output currents may be generated among the conventional driver's data driver chips. However, according to exemplary embodiments of the present invention, the data driver chips in the data driver include the master data driver chip and slave data driver chips, and the master data driver chip generates and supplies the reference current Iref to the slave data driver chips, which may significantly reduce deviation in output currents among the data driver chips.

As described above, according to an exemplary embodiment of the present invention, the data driver chips in the current data driver share the reference current so that it is possible to provide a more uniform output current among the data driver chips in spite of changes in external resistances.

FIG. 4 schematically shows a data driver according to a second exemplary embodiment of the present invention that has a plurality of data driver chips and that may be used for the light emitting display of FIG. 2.

Referring to FIG. 4, the data driver 200 includes first, second, third and fourth data driver chips 210, 220, 230 and 240.

The first data driver chip 210, which is referred to as the master data driver chip, generates differential reference currents Iref1 and Iref2 using the reference voltage Vref and the external resistance Rext and transmits the differential reference currents Iref1 and Iref2 to the second data driver chip 220. The relationship among the differential reference currents Iref1 and Iref2, the reference voltage Vref, and the external resistance Rext may be represented by EQUATION 1.
(Iref2−Iref1)∝(Vref/Rext) [EQUATION 1]

That is, the difference between the differential reference currents Iref1 and Iref2 is proportional to the value obtained by dividing the reference voltage Vref by the external resistance Rext. EQUATION 2 provides values for the differential reference currents.
Iref1=(Vref/Rext)
Iref2=2×(Vref/Rext) [EQUATION 2]

The second data driver chip 220 generates the differential reference currents Iref1 and Iref2 using the input differential reference currents Iref1 and Iref2 from the first data driver chip 210 and transmits the differential reference currents Iref1 and Iref2 to the third data driver chip 230. The third data driver chip 230 generates the differential reference currents Iref1 and Iref2 using the input differential reference currents Iref1 and Iref2 from the second data driver chip 220 and transmits the differential reference currents Iref1 and Iref2 to the fourth data driver chip 240. The data driver chips that either generate the output differential reference currents using the input differential reference currents or receive the input differential reference currents are referred to as slave data driver chips.

Since each data driver chip 210, 220, 230 and 240 has 300 channel outputs, the data driver of FIG. 4 may have a maximum 1,200 channel outputs. The data driver chips 210, 220 and 230 supply the currents corresponding to the differential reference currents Iref1 and Iref2 to the data driver chips 220, 230 and 240, respectively. Further, the data driver chips 210, 220, 230 and 240 supply the reference current Iref (or reference currents Iref1 and Iref2), which corresponds to the difference between the differential reference currents Iref1 and Iref2, to a D/A converter (not shown). In the D/A converter, the supplied reference current Iref determines the current value corresponding to each gray scale. Meanwhile, the 4^{th} data driver chip 240 is placed at the last terminal of the data driver, so that it does not output the differential reference currents Iref1 and Iref2.

As described above, only the master data driver chip 210 generates the reference current and the differential reference currents Iref1 and Iref2 using the reference voltage Vref and the external resistance Rext. The slave data driver chips 220, 230 and 240 generate the reference current and the differential reference currents Iref1 and Iref2 using the differential reference currents Iref1 and Iref2 transmitted from the master data driver chip 210 or the slave data driver chips 220 and 230. Therefore, it is possible to maintain substantially uniform reference currents used by the data driver chips 210, 220, 230 and 240 so that it is possible to improve uniformity in picture quality. Also, the differential reference currents Iref1 and Iref2 may be used as the currents transmitted among the data driver chips 210, 220, 230 and 240 so that it is possible to increase a common mode rejection ratio (CMRR).

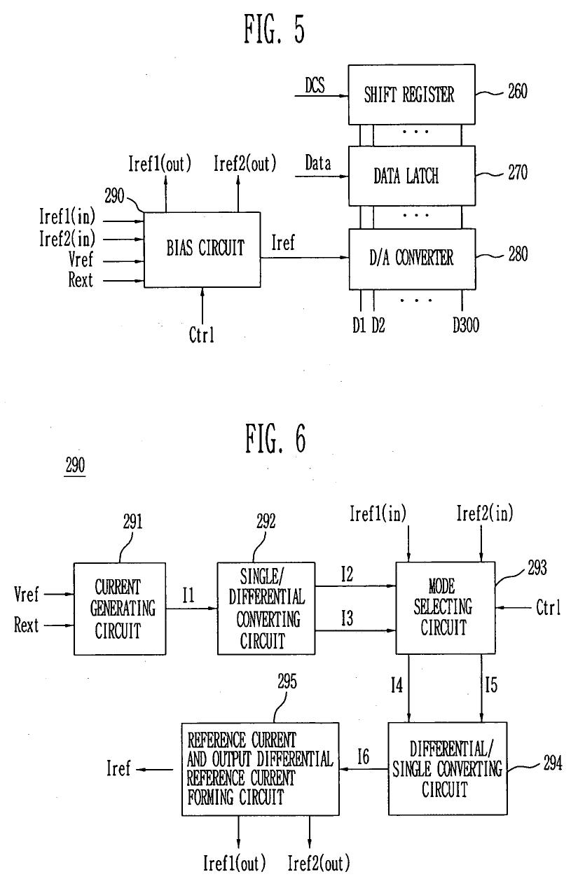

FIG. 5 shows an example of a data driver chip that may be used for the data driver of FIG. 4.

Referring to FIG. 5, the data driver chip includes a shift register 260, a data latch 270, a D/A converter 280, and a bias circuit 290.

The shift register 260 controls the data latch 270 by outputting a latch control signal in response to a horizontal clock signal HCLK and a horizontal synchronizing signal HSYNC, which are included in the data driver control signals DCS of FIG. 2.

The data latch 270 sequentially receives video data Data to output the video data Data in parallel to the D/A converter 280. The data latch 270 is controlled by the latch control signals output from the shift register 260.

The D/A converter 280 converts the signals output in parallel from the data latch 270 into analog currents to output the analog currents. The current corresponding to each gray scale is determined by the reference current Iref transmitted from the bias circuit 290.

The bias circuit 290 may be used for the master data driver chip and the slave data driver chips. When the bias circuit 290 operates in a master mode, that is, when a mode control signal Ctrl corresponds to a first mode, the master mode is applied. In the master mode, the bias circuit 290 generates the reference current Iref using the reference voltage Vref and the external resistance Rext to transmit the reference current Iref to the D/A converter 280 and generates output differential reference currents Iref1 (out) and Iref2 (out) using the reference voltage Vref and the external resistance Rext to output the output differential reference currents Iref1 (out) and Iref2(out). When the bias circuit 290 operates in a slave mode, that is, when the mode control signal Ctrl corresponds to a second mode, the slave mode is applied. In the slave mode, the bias circuit 290 generates the reference current Iref using input differential reference currents Iref1 (in) and Iref2 (in) to transmit the reference current Iref to the D/A converter 280 and generates the output differential reference currents Iref1 (out) and Iref2 (out) using the input differential reference currents Iref1 (in) and Iref2 (in) to output the output differential reference currents Iref1 (out) and Iref2(out).

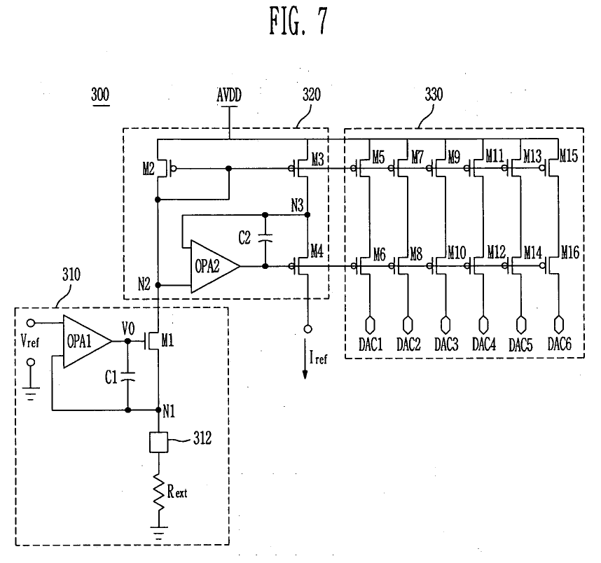

FIG. 6 shows an example of a bias circuit that may be used for the data driver chip of FIG. 5.

Referring to FIG. 6, the bias circuit 290 includes a current generating circuit 291, a single/differential converting circuit 292, a mode selecting circuit 293, a differential/single converting circuit 294, and a reference current and output differential reference current forming circuit 295.

The current generating circuit 291 generates a first current I1 using the reference voltage Vref and the external resistance Rext. The first current may have the value obtained by EQUATION 3.
I1=(Vref/Rext) [EQUATION 3]

The single/differential converting circuit 292 converts the first current I1 into differential currents I2 and I3. The differential currents I2 and I3 output from the single/differential converting circuit 292 may have the values obtained by EQUATION 4.
I2=I1
I3=2×I1 [EQUATION 4]

The mode selecting circuit 293 outputs either the differential currents I2 and I3 or the input differential reference currents Iref1 (in) and Iref2 (in) in accordance with the mode control signal Ctrl. The mode selecting circuit 293 outputs the differential currents I2 and I3 when the mode control signal Ctrl corresponds to the master mode, and it outputs the input differential reference currents Iref1 (in) and Iref2 (in) when the mode control signal Ctrl corresponds to the slave mode. Hence, differential currents I4 and I5 output from the mode selecting circuit 293 may have the values obtained by EQUATION 5.
I4=I2, I5=I3 (In case of the master mode)
I4=Iref1(in), I5=Iref2(in) (In case of the slave mode) [EQUATION 5]

The differential/single converting circuit 294 converts the differential currents output from the mode selecting circuit 293 into a single current I6. The single current I6 output from the differential/single converting circuit 294 may have the value obtained by EQUATION 6.
I6=I5−I4 [EQUATION 6]

The reference current and output differential reference current forming circuit 295 generates the reference current Iref and the output differential reference currents Iref1 (out) and Iref2 (out) from the single current 16 output from the differential/single converting circuit 294. The reference current Iref and the output differential reference currents Iref1 (out) and Iref2 (out) may have the values obtained by EQUATION 7.
Iref=I6
Iref1(out)=I6
Iref2(out)=2×I6 [EQUATION 7]

When the bias circuit 290 is in master mode, the current generating circuit 291 generates the first current I1, the single/differential converting circuit 292 converts the first current I1 into the differential currents I2 and I3, the differential/single converting circuit 294 converts the differential currents I2 and I3 (per EQUATION 5, I4=I2 and I5=I3) into the single current I6, and the reference current and output differential reference current forming circuit 295 generates the reference current Iref and the output differential reference currents Iref1 (out) and Iref2(out) using the single current I6. On the other hand, when the bias circuit 290 is in slave mode, the mode selecting circuit 293 receives the input differential reference currents Iref1 (in) and Iref2 (in), the differential/single converting circuit 294 converts the input differential reference currents Iref1 (in) and Iref2 (in) (per EQUATION 5, I4=Iref1 (in) and I5=Iref2 (in)) into the single current I6, and the reference current and output differential reference current forming circuit 295 generates the reference current Iref and the output differential reference currents Iref1 (out) and Iref2(out) using the single current I6.

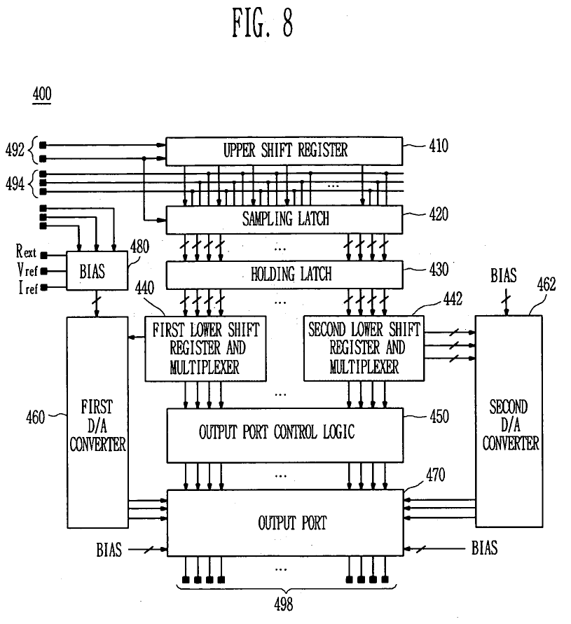

FIG. 7 shows a current generating circuit that may be used for the data driver according to the first and second exemplary embodiments of the present invention.

Referring to FIG. 7, the current generating circuit 300 generates the reference current Iref, which is to be commonly used by all of the data driver chips (the master data driver chip and the slave data driver chips), in the master data driver chip to supply the reference current Iref in order to make the levels of the output currents of the D/A converters in the plurality of data driver chips substantially uniform. The current generating circuit 300 includes a first circuit 310, a second circuit 320, and a third circuit 330.

The first circuit 310 includes a first operation amplifier OPA1, a first capacitor C1 and a first transistor M1, which is an n-type transistor.

The first operation amplifier OPA1 includes a first input terminal to which the reference voltage Vref is input, a second input terminal coupled with a second electrode of the first transistor M1, and an output terminal coupled with the gate of the first transistor M1.

The first transistor M1 includes a first electrode, the second electrode, and a gate. The first electrode of the first transistor M1 is coupled with a bias power source AVDD, and the second electrode of the first transistor M1 is coupled with the resistance Rext arranged outside the current generating circuit 300 through a pad 312. The first transistor M1 operates so that the current generated by the bias power source AVDD flows from the first electrode of the first transistor M1 to the second electrode of the first transistor M1 in accordance with the first transistor's gate voltage.

The first capacitor C1, which stores the voltage corresponding to the difference in voltage between the gate of the first transistor M1 and a first node N1, is coupled between the gate of the first transistor M1 and the first node N1. The first capacitor C1 maintains the first transistor M1 to be turned on so that desired current flows through the first transistor M1 by the stored voltage.

With this configuration, the first circuit 310 operates so that the reference voltage Vref may be stably applied to the first node N1 and that desired current flows through the first transistor M1 by the first operation amplifier OPA1 and the negative feedback loop of the n-type first transistor M1.

Next, the second circuit 320 copies the current that flows through the first circuit 310 to generate the reference current Iref. The second circuit 320 includes a second transistor M2, a third transistor M3, a second operation amplifier OPA2, a second capacitor C2, and a fourth transistor M4. Here, the second to fourth transistors M2, M3, and M4 are p-type transistors.

The second transistor M2 includes a first electrode, a second electrode, and a gate. The first electrode of the second transistor M2 is coupled with a power source line that supplies the bias power source AVDD, and the second electrode of the second transistor M2 is coupled with the gate of the second transistor M2.

The third transistor M3 includes a first electrode, a second electrode, and a gate. The first electrode of the third transistor M3 is coupled with the power source line that supplies the bias power source AVDD together with the first electrode of the second transistor M2, the second electrode of the third transistor M3 is coupled with the first electrode of the fourth transistor M4 and the second input terminal of the second operation amplifier OPA2, and the gate of the third transistor M3 is coupled with the gate of the second transistor M2. Therefore, the second and third transistors M2 and M3 have a mirror structure, and the current that flows through the second transistor M2 may be copied to flow through the third transistor M3.

The second operation amplifier OPA2 includes a first input terminal, a second input terminal, and an output terminal. The voltage of a second node N2, to which the second electrode of the second transistor M2 is coupled, is applied to the first input terminal of the second operation amplifier OPA2. The second input terminal of the second operation amplifier OPA2 is coupled with the first electrode of the fourth transistor M4. The output terminal of the second operation amplifier OPA2 is coupled with the gate of the fourth transistor M4.

The fourth transistor M4 includes a first electrode, a second electrode, and a gate. The first electrode of the fourth transistor M4 is coupled with the second electrode of the third transistor M3 and the second input terminal of the second operation amplifier OPA2. The gate of the fourth transistor M4 is coupled with the output terminal of the second operation amplifier OPA2.

The second capacitor C2, which stores the voltage corresponding to the difference in voltage between the gate of the fourth transistor M4 and a third node N3, is coupled between the gate of the fourth transistor M4 and the third node N3. The second capacitor C2 maintains the fourth transistor M4 to be turned on so that the copied current flows through the fourth transistor M4 by the stored voltage.

With this configuration, the second circuit 320 maintains the voltages of the second electrodes of the second and third transistors M2 and M3, that is, drain voltages, substantially uniform using the second operation amplifier OPA2 and the negative feedback circuit of the fourth transistor M4. In other words, the second circuit 320 compensates for a difference in characteristics between the second and third transistors M2 and M3 so that the third transistor M3 precisely copies the current that flows through the second transistor M2.

Next, the third circuit 330 copies the current that flows through the second transistor M2, like the third transistor M3 that copies the current that flows through the second transistor M2, to supply the current to the respective D/A converters. The third circuit 330 includes fifth to sixteenth transistors M5, M6, M7, M8, M9, M10, M11, M12, M13, M14, M15, and M16 that supply the copied reference current to first to sixth D/A converters DAC1, DAC2, DAC3, DAC4, DAC5, and DAC6.

The 5^{th}, 7^{th}, 9^{th}, 11^{th}, 13^{th}, and 15^{th} transistors are coupled with the second transistor M2 like the third transistor M3 to form a mirror structure. The 6^{th}, 8^{th}, 10^{th}, 12^{th}, 14^{th}, and 16^{th} transistors are turned on when the fourth transistor M4 is turned on so that the current copied by the second transistor M2 may be supplied to the D/A converters DAC1, DAC2, DAC3, DAC4, DAC5, and DAC6.

As described above, the current generating circuit generates the reference current determined by the reference voltage and the external resistance and copies the reference current to supply the copied current to the D/A converters. Also, the current generating circuit supplies the generated reference current to the slave data driver chips so that the respective data driver chips generate substantially uniform output currents.

FIG. 8 shows an example of a data driver chip that may be used for the light emitting display of FIG. 2. The data driver chip includes current mode D/A converters, and the signals input to and output from the D/A converters are multiplexed and then demultiplexed. First, the reason why such a structure is adopted will be simply described.

In case of the conventional TFT-LCD integrated circuit data driver chip, each channel commonly includes a D/A converter and an output port buffer circuit, and 300 to 480 channels may be integrated in one data driver chip. Also, the pads of all of the output channels are arranged on one longitudinal side. Assuming that the maximum length of the longitudinal side of the data driver chip is 20,000 μm and the number of output channels is 300, the channel pitch is about 67 μm. The D/A converter used for the TFT-LCD integrated circuit data driver chip commonly has a ROM decoder structure. Therefore, the D/A converter can be integrated within 67 μm.

However, in case of a current mode (constant current driving) integrated circuit data driver chip, the outputs of the D/A converters are currents. Therefore, current mode D/A converters are utilized. Since the area occupied by the current mode D/A converters is very large, it is difficult to integrate the D/A converters in all of the output channels. Therefore, according to the integrated circuit data driver chip of an embodiment of the present invention, the input side and the output side of the D/A converter are provided with a multiplexer and a demultiplexer, respectively, so that one D/A converter may be in charge of the outputs of various channels.

To be specific, referring to FIG. 8, the data driver chip 400 includes a first driving circuit that samples and stores input digital video data, a second driving circuit for converting the stored digital video data into analog data signals, and a bias or a bias circuit that controls the second driving circuit using the control signals and the reference current. Here, the first and second driving circuits may be referred to as a digital circuit and an analog circuit, respectively.

The first driving circuit includes an upper shift register 410, a sampling latch 420, a holding latch 430, a first lower shift register and multiplexer 440 (hereinafter, referred to as a first lower shift register), a second lower shift register and multiplexer 442 (hereinafter, referred to as a second lower shift register), and an output port control logic 450.

The upper shift register 410 receives control signals such as a synchronizing signal and a clock signal through a first input terminal 492 and generates a latch control signal for controlling the sampling latch 420 and the holding latch 430.

The sampling latch 420 and the holding latch 430 sample and store digital video data input through a second input terminal 494 in accordance with the latch control signal of the upper shift register 410. Here, the digital video data may be, for example, 10-bit red, green and blue (RGB) video data signals.

The first and second lower shift registers 440 and 442 transmit the 10-bit digital video data stored in the holding latch 430 to first and second D/A converters 460 and 462, respectively. At this time, the first and second lower shift registers 440 and 442 multiplex the digital video data through the multiplexer to transmit the multiplexed digital video data to the first and second D/A converters 460 and 462 so that one D/A converter may be in charge of the outputs of various channels.

The output port control logic 450 receives control signals from the first and second lower shift registers 440 and 442 to control an output port 470 so that the digital video data transmitted from the first and second lower shift registers 440 and 442 to the first and second D/A converters 460 and 462 and converted into analog data signals are properly output from the output port 470.

Next, the analog circuit includes the first D/A converter 460, the second D/A converter 462, and the output port 470.

The first and second D/A converters 460 and 462 convert the digital video data received from the first and second lower shift registers 440 and 442, respectively, into analog data signals. At this time, the first and second D/A converters 460 and 462 have the output levels of the analog data signals determined in accordance with the reference current Iref. Also, the demultiplexer that selectively supplies a data signal output through one line to a plurality of lines may be combined with the output port of the first and second D/A converters 460 and 462. The analog data signals, that is, the output current signals of the first and second D/A converters 460 and 462, are transmitted to the output port 470.

The output port 470 outputs the output current signals received from the first and second D/A converters 460 and 462 through a channel 498 coupled with the output port 470. The currents output from the output port 470 drive the pixels of the light emitting display.

The bias circuit 480 generates the reference current Iref based on the external resistance Rext coupled with the input terminal and the external voltage Vref applied to the other input terminal and supplies the generated reference current to the first and second D/A converters 460 and 462 and the output port 470. The generated reference current Iref is supplied to the other data driver chips in the data driver.

As described above, according to exemplary embodiments of the present invention, the reference current or the differential reference currents are generated in a first data driver chip in the data driver, and the generated reference current or the generated differential reference currents are supplied to second data driver chips so that it is possible to make the output currents of the data driver chips substantially uniform. Therefore, the light emitting display including a data driver according to the present invention may realize high picture quality.

Further, according to the data driver chips and the light emitting display of exemplary embodiments of the present invention, it is possible to reduce errors in the reference currents used by the respective data driver chips, thereby improving uniformity in picture quality.

Furthermore, according to the data driver chips and the light emitting display of exemplary embodiments of the present invention, the differential reference currents are used as the currents transmitted among the data driver chips so that it is possible to improve a CMRR.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A light emitting display, comprising:
a scan driver for applying scan signals to a plurality of scan lines;
a data driver for applying data currents to a plurality of data lines; and
an image display unit for displaying images in accordance with the scan signals and the data currents,
wherein the data driver comprises:
a first data driver chip for outputting a reference current; and
a second data driver chip for receiving the reference current output from the first data driver chip.

2. The light emitting display of claim 1, wherein the reference current output by the first data driver chip is determined by a reference voltage and a resistance.

3. The light emitting display, comprising:
a scan driver for applying scan signals to a plurality of scan lines;
a data driver for applying data currents to a plurality of data lines; and
an image display unit for displaying images in accordance with the scan signals and the data currents,
wherein the data driver comprises:
a first data driver chip for outputting differential reference currents; and
a second data driver chip for receiving the differential reference currents output from the first data driver chip.

4. The light emitting display of claim 3, wherein the differential reference currents output by the first data driver chip are determined by a reference voltage and a resistance.

5. The light emitting display of claim 4,
wherein the second data driver chip outputs differential reference currents corresponding to the differential reference currents output from the first data driver chip, and
wherein the data driver further comprises a third data driver chip for receiving the differential reference currents output from the second data driver chip.

6. The light emitting display of claim 4, wherein a difference in values of the differential reference currents output from the first data driver chip is proportional to a value obtained by dividing a value of the reference voltage by a value of the resistance.

7. The light emitting display of claim 4,
wherein a value of a first current of the differential reference currents output from the first data driver chip corresponds to a value obtained by dividing a value of the reference voltage by a value of the resistance, and
wherein a value of a second current of the differential reference currents output from the first data driver chip corresponds to a value that is substantially twice the value obtained by dividing the value of the reference voltage by the value of the resistance.

8. The light emitting display of claim 4, wherein, in the first data driver chip, values of data currents corresponding to gray scales are determined by the reference voltage and the resistance.

9. The light emitting display of claim 4, wherein, in the second data driver chip, values of data currents corresponding to gray scales are determined by the differential reference currents output from the first data driver chip.

10. The light emitting display of claim 4, wherein the resistance is arranged outside the first data driver chip.

11. The light emitting display of claim 4, further comprising:
a timing controller,
wherein the timing controller transmits scan driver control signals to the scan driver and data driver control signals and video data to the data driver.

12. The light emitting display of claim 4, wherein values of differential reference currents output from the second data driver chip are substantially equal to values of the differential reference currents output from the first data driver chip.

13. The light emitting display of claim 5, wherein, in the third data driver chip, values of data currents corresponding to gray scales are determined by the differential reference currents output from the second data driver chip.

14. The light emitting display of claim 4, wherein the first data driver chip and the second data driver chip each comprise a digital to analog converter, a multiplexer and a demultiplexer, the multiplexer and the demultiplexer being arranged at an input side and an output side, respectively, of the digital to analog converter.

15. A data driver chip, comprising:
a shift register for outputting a latch control signal in response to a clock signal and a synchronizing signal;
a data latch for sequentially receiving video data to output the video data in parallel in accordance with the latch control signal;
a digital to analog (D/A) converter for outputting data currents obtained by analog converting the video data output from the data latch; and
a bias circuit for generating a reference current and an output reference current using a reference voltage and a resistance when a first control signal is applied, for generating the reference current and the output reference current using an input reference current when a second control signal is applied, and for transmitting the reference current to the D/A converter and outputting the output reference current.

16. A data driver chip, comprising:
a shift register for outputting a latch control signal in response to a clock signal and a synchronizing signal;
a data latch for sequentially receiving video data to output the video data in parallel in accordance with the latch control signal;
a digital to analog (D/A) converter for outputting data currents obtained by analog converting the video data output from the data latch; and
a bias circuit for generating a reference current and output differential reference currents using a reference voltage and a resistance when a first control signal is applied, for generating the reference current and the output differential reference currents using input differential reference currents when a second control signal is applied, and for transmitting the reference current to the D/A converter and outputting the output differential reference currents.

17. The data driver chip of 16, wherein, in the D/A converter, values of data currents corresponding to gray scales are determined by the reference current.

18. The data driver chip of 16, wherein, when the first control signal is applied to the bias circuit, a value of the reference current corresponds to a value obtained by dividing a value of the reference voltage by a value of the resistance, a value of a first current of the output differential reference currents corresponds to the value obtained by dividing the value of the reference voltage by the value of the resistance, and a value of a second current of the output differential reference currents corresponds to a value that is substantially twice the value obtained by dividing the value of the reference voltage by the value of the resistance.

19. The data driver chip of claim 16, wherein, when the second control signal is applied to the bias circuit, a value of the reference current corresponds to a difference between values of the input differential reference currents, and values of the output differential reference currents correspond to the values of the input differential reference currents.

20. The data driver chip of claim 14, wherein the resistance is arranged outside the first data driver chip.

21. The data driver chip of claim 16, further comprising:
a current generating circuit for generating the reference current,
wherein the current generating circuit comprises:
a first operation amplifier comprising a first input terminal, a second input terminal, and an output terminal, the reference voltage being input to the first input terminal of the first operation amplifier; and
a first transistor comprising a first electrode, a second electrode, and a gate, the gate of the first transistor being coupled with the output terminal of the first operation amplifier, the first electrode of the first transistor being coupled with a power source line that supplies a bias power, and the second electrode of the first transistor being coupled with the second input terminal of the first operation amplifier and a first end of the resistance,
wherein a second end of the resistance is grounded.

22. The data driver chip of claim 21,
wherein the current generating circuit further comprises:
a second transistor comprising a first electrode, a second electrode, and a gate, the gate of the second transistor being coupled with the second electrode of the second transistor, the first electrode of the second transistor being coupled with the power source line that supplies the bias power, and the second electrode of the second transistor being coupled with the first electrode of the first transistor;
a third transistor comprising a first electrode, a second electrode, and a gate, the gate of the third transistor being coupled with the gate of the second transistor, and the first electrode of the third transistor being coupled with the first electrode of the second transistor and the power source line that supplies the bias power;
a second operation amplifier comprising a first input terminal, a second input terminal, and an output terminal, the first input terminal of the second operation amplifier being coupled with the first electrode of the first transistor, and the second input terminal of the second operation amplifier being coupled with the second electrode of the third transistor; and
a fourth transistor comprising a first electrode, a second electrode, and a gate, the first electrode of the fourth transistor being coupled with the second electrode of the third transistor and the second input terminal of the second operation amplifier, and the gate of the fourth transistor being coupled with the output terminal of the second operation amplifier.
